(19) United States
(12) Patent Application Publication
(10) Pub. No.: US 2006/0068126 A1
(43) Pub. Date: Mar. 30, 2006

(54) Method for making an aligned carbon nanotube

(75) Inventors: Jyh-Ming Ting, Taipei City (TW); Kun-Hou Liao, Tainan City (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: NATIONAL CHENG KUNG UNIVERSITY, Tainan City (TW)

(21) Appl. No.: 11/030,364

(22) Filed: Jan. 5, 2005

(30) Foreign Application Priority Data
Sep. 30, 2004 (TW) 093129621

(51) Int. Cl. C23C 16/00

(52) U.S. Cl. 427/569; 427/248.1

(57) ABSTRACT

A method for making an aligned carbon nanotube includes the steps of a) applying a layer of a ferrosilicon alloy film onto a substrate, b) etching the layer of the ferrosilicon film to form a plurality of fine ferrosilicon alloy particles that are distributed properly on the substrate, and c) placing the substrate of step (b) into a microwave plasma enhanced chemical vapor deposition system, and supplying a mixture of a carbon-containing reaction gas and a balance gas at a predetermined flow ratio so as to grow carbon nanotubes on the fine ferrosilicon alloy particles.

### CROSS-REFERENCE TO RELATED APPLICATION

This application claims priority of Taiwanese Application No. 093129621, filed on Sep. 30, 2004.

### BACKGROUND OF THE INVENTION

1. Field of the Invention

The invention relates to a method for making an aligned carbon nanotube, more particularly to a method for making an aligned carbon nanotube at a relatively low temperature.

2. Description of the Related Art

Chemical vapor deposition (referred to as CVD hereinafter) and related techniques derived therefrom, such as microwave plasma enhanced chemical vapor deposition (referred as to MPCVD hereinafter), are commonly used to make a carbon nanotube. In the CVD method or the related techniques, a porous substrate coated with a catalyst is placed in a CVD or MPCVD system. A carbon-containing reaction gas suitable for growing the carbon nanotube is introduced into the CVD or MPCVD system. The carbon-containing reaction gas is cleaved or ionized so as to react with the catalyst on the substrate and to grow the carbon nanatube.

Although the aforesaid conventional method can be used to make the carbon nanotube, the conventional method has to be conducted at a relatively high temperature and at a relatively slow reaction rate.

The reaction temperature and the reaction rate at which the carbon nanotube is made are affected primarily by the composition of the catalyst. The main function of the catalyst is to react with the carbon atoms produced by cleaving the carbon-containing reaction gas via a plasma process so as to deposit and grow the carbon nanotube. The growth rate of the carbon nanotube is affected by the activity of the catalyst, which is restricted by the reaction temperature. The catalyst used in the conventional CVD or MPCVD process requires a relatively high catalysis temperature, which is generally higher than 550° C.

### SUMMARY OF THE INVENTION

The object of the present invention is to provide a method for making an aligned carbon nanotube which can be conducted at a relatively low temperature.

Accordingly, a method for making an aligned carbon nanotube of this invention includes the steps of:
(a) applying a layer of a ferrosilicon alloy film onto a substrate;
(b) etching the layer of the ferrosilicon film to form a plurality of fine ferrosilicon alloy particles that are distributed properly on the substrate; and
(c) placing the substrate of step (b) into a microwave plasma enhanced chemical vapor deposition system, and supplying a mixture of a carbon-containing reaction gas and a balance gas at a predetermined flow ratio so as to grow carbon nanotubes on the fine ferrosilicon alloy particles.

### BRIEF DESCRIPTION OF THE DRAWINGS

Other features and advantages of the present invention will become apparent in the following detailed description of the preferred embodiment with reference to the accompanying drawings, of which:

FIGS. 1, 2 and 3 are schematic views showing the consecutive steps of the preferred embodiment of a method for making an aligned carbon nanobute according to this invention;

FIG. 4 is a field emitted sweep electron microscopic view showing the profile and distribution of a plurality of the carbon nanotubes made according to the preferred embodiment; and

FIG. 5 is a transmission electron microscopic view showing a tubular structure of a single one of the nanotubes made according to the preferred embodiment.

### DETAILED DESCRIPTION OF THE PREFERRED EMBODIMENT

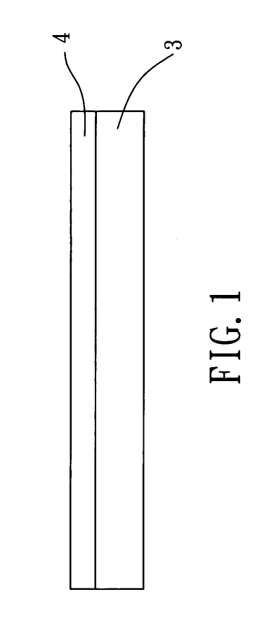

Referring to FIGS. 1, 2 and 3, the preferred embodiment of the method for making an aligned carbon nanotube according to this invention includes the following steps:

A) Applying:

As shown in FIG. 1, a layer of a ferrosilicon alloy film 4 is applied onto a substrate 3 by sputtering. The ferrosilicon alloy film 4 is used as a catalyst for growing carbon nanotubes in the preferred embodiment. Since silicon contained in the ferrosilicon alloy can improve the diffusion capability of carbon atoms and the catalytic activity of iron contained in the ferrosilicon alloy, the temperature required to enhance the catalytic activity can be lowered. In the preferred embodiment, the sputtering process is conducted for a period of about 3 minutes at a sputtering power of about 50 W under a working pressure of about 10⁻² Torr.

The substrate used in the preferred embodiment is silicon substrate. However, other materials well known in the art, such as polymeric materials, can also be used. Additionally, while sputtering is employed in this invention, other processes well known in the art, such as chemical vapor deposition, physical vapor deposition, electroplating, printing, and the like, can also be used.

B) Etching:

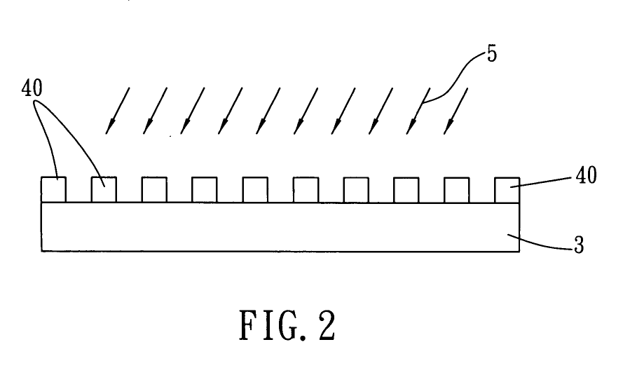

As shown in FIG. 2, the substrate 3 coated with the layer of the ferrosilicon film 4 is placed in an MPCVD system (not shown), and an etching gas 5 is introduced into the MPCVD system to etch the ferrosilicon film 4 so as to form a plurality of fine ferrosilicon alloy particles 40 that are distributed properly on the substrate 3. The size of the ferrosilicon alloy particles 40 ranges from 5 to 25 nm, and the distribution density thereof ranges from 3×10¹⁰ to 4×10¹⁰ cm⁻².

Hydrogen is used as the etching gas in this preferred embodiment. However, other suitable gases well known in the art, such as oxygen, nitrogen, and ammonia, can also be used. If desired, a mixture of at least two of the aforesaid gases can be used as the etching gas. The etching process is conducted for a period of about 5 minutes at a microwave power of about 500 W under a working pressure of about 20 Torr. The size and the distribution density of the ferrosilicon alloy particles 40 can be adjusted according to the etching conditions, such as the microwave power, the working pressure, the etching time, and the like.

C) Growing the Carbon Nanotubes:

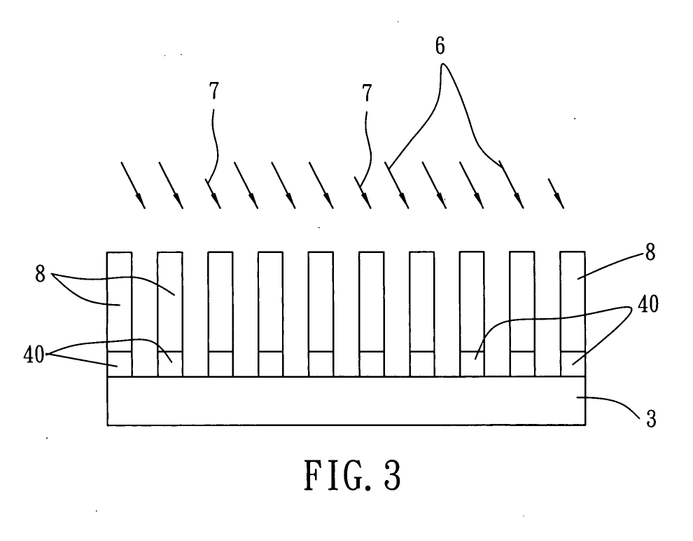

As shown in FIG. 3, a mixture of a carbon-containing reaction gas 6 and a balance gas 7 at a predetermined flow ratio is supplied to the MPCVD system to grow carbon nanotubes 8 on the ferrosilicon alloy particles 40 along a substantially vertical direction at a temperature ranging from 300 to 380° C. Since the MPCVD technique is well known to the skilled artisan, it will not be described in detail herein for the sake of brevity.

The balance gas 7 is used for cleaning and reducing the ferrosilicon alloy particles 40 during the process of growing the carbon nanotubes 8. Therefore, when the balance gas 7 is introduced into the MPCVD system along with the carbon-containing reaction gas 6, the balance gas 7 can clean up amorphous carbon which is adsorbed on the ferrosilicon alloy particles 40 and which may interfere with entry of the desired carbon atoms into the ferrosilicon alloy particles 40. Therefore, the carbon atoms resulted from the cleaving of the carbon-containing reaction gas 6 can diffuse among and interact with the ferrosilicon alloy particles 40 so as to grow the carbon nanotubes 8. The growth of the carbon nanotubes 8 can be improved by controlling the flow ratio of the carbon-containing reaction gas 6 to the balance gas 7. The carbon-containing reaction gas 6 and the balance gas 7 used in this preferred embodiment are methane and hydrogen, respectively, and the flow ratio of the carbon-containing reaction gas 6 to the balance gas 7 is preferably 2:9. Preferably, the carbon nanotubes 8 are grown at a microwave power ranging from 250 to 1500 W under a working pressure ranging from 20 to 40 Torr. In addition, while methane is used as the carbon-containing reaction gas in this preferred embodiment, other suitable gases, such as ethane, propane, ethyne, benzene, and the like, can also be used. If desired, a mixture of at least two of methane, ethane, propane, ethyne, benzene, and the like can be used as the carbon-containing reaction gas 6. Furthermore, in addition to hydrogen, other suitable gases, such as oxygen, nitrogen, and ammonia, can be used as the balance gas 7. If desired, a mixture of at least two of hydrogen, oxygen, nitrogen, and ammonia can be used as the balance gas 7 in this invention.

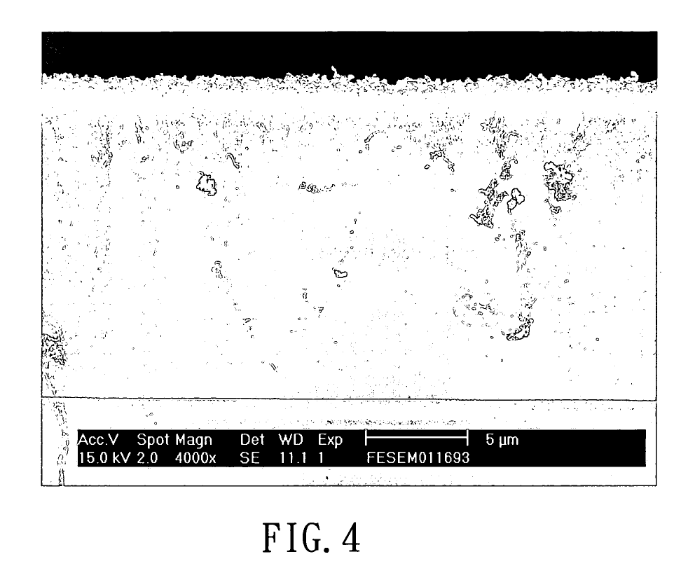

The carbon nanotubes 8 made according to the preferred embodiment is shown in FIG. 4. The distribution density, the tube size, and the growth rate of the carbon nanotubes 8 are 3×10¹⁰-4×10¹⁰ cm⁻², 5-25 nm, and 13 um/min, respectively. The ratio of height to diameter of each of the carbon nanotubes 8 ranges from 1500:1 to 7500:1.

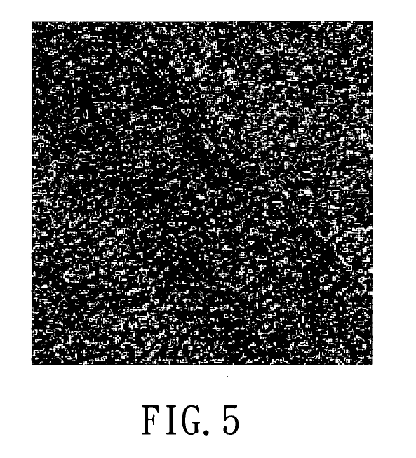

The structure of a single one of the carbon nanotubes 8 is shown in FIG. 5, in which the tube diameter is 11 nm. The tubular wall of each of carbon nanotubes 8 is composed of 8 graphite layers, and has an integral structure.

In view of the aforesaid, in the method of this invention, since the ferrosilicon film 4 has an improved catalytic activity, the diffusion rate of the carbon atoms, which are obtained by cleaving the carbon-containing reaction gas 6, into the ferrosilicon film 4 can be increased. Therefore, the temperature required for growing the carbon nanotubes 8 is reduced. Furthermore, the relatively high distribution density of the ferrosilicon alloy particles 40 and the designed flow ratio of the carbon-containing reaction gas 6 to the balance gas 7 result in the growth of the carbon nanotubles 8 at a distribution density up to 4×10¹⁰ cm⁻² and at a growth rate up to 13 um/min. Therefore, the productivity of the carbon nanotubes 8 can be increased so as to reduce production costs. Since the carbon nanotube 8 made according to this invention is characterized by a relatively small tube diameter distribution and a relatively high ratio of height to diameter, and requires a relatively low temperature during the growing process, the method for making an aligned carbon nanotube according to this invention can be used in various applications, such as field emitted flat displays, integrated circuits, biochips, and the like.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

I claim:

1. A method for making an aligned carbon nanotube, comprising the steps of:
(a) applying a layer of a ferrosilicon alloy film onto a substrate;
(b) etching the layer of the ferrosilicon film to form a plurality of fine ferrosilicon alloy particles that are distributed properly on the substrate; and
(c) placing the substrate of step (b) into a microwave plasma enhanced chemical vapor deposition system, and supplying a mixture of a carbon-containing reaction gas and a balance gas at a predetermined flow ratio so as to grow carbon nanotubes on the fine ferrosilicon alloy particles.

2. The method as claimed in claim 1, wherein step (c) is conducted at a temperature ranging from 300 to 380° C.

3. The method as claimed in claim 1, wherein step (c) is conducted at a microwave power ranging from 250 to 1500 W and at a working pressure ranging from 20 to 40 Torr.

4. The method as claimed in claim 1, wherein the substrate is selected from the group consisting of silicon substrates and polymer substrates.

5. The method as claimed in claim 1, wherein step (a) is conducted by a process selected from the group consisting of sputtering, chemical vapor deposition, physical vapor deposition, electroplating, and printing.

6. The method as claimed in claim 1, wherein step (b) is conducted by placing the substrate coated with the layer of the ferrosilicon alloy film in the microwave plasma enhanced chemical vapor deposition system and supplying an etching gas into the microwave plasma enhanced chemical vapor deposition system.

7. The method as claimed in claim 6, wherein the etching gas includes at least one gas selected from the group consisting of hydrogen, oxygen, nitrogen, and ammonia.

8. The method as claimed in claim 6, wherein each of the fine ferrosilicon alloy particles has a particle size ranging from 5 to 25 nm.

9. The method as claimed in claim 6, wherein the fine ferrosilicon alloy particles have a distribution density ranging from 3×10¹⁰ to 4×10¹⁰ cm⁻².

10. The method as claimed in claim 1, wherein the predetermined flow ratio of the carbon-containing reaction gas to the balance gas is 2:9.

11. The method as claimed in claim 10, wherein the carbon-containing reaction gas includes at least one gas selected from the group consisting of methane, ethane, propane, ethyne, and benzene.

12. The method as claimed in claim 10, wherein the balance gas includes at least one gas selected from the group consisting of hydrogen, oxygen, nitrogen, and ammonia.
